(19) United States
(12) Patent Application Publication
(10) Pub. No.: US 2010/0188805 A1
(43) Pub. Date: Jul. 29, 2010

(54) COVER RELEASING MECHANISMS

(75) Inventors: Cuiyu ZHOU, Shanghai (CN); Ming WEN, Shanghai (CN); Chuan-Ting HSU, Shanghai (CN)

Correspondence Address: MCDERMOTT WILL & EMERY LLP, 600 13TH STREET, N.W., WASHINGTON, DC, 20005-3096, US

(73) Assignees: INVENTEC APPLIANCES (SHANGHAI)CO.,LTD.; INVENTEC APPLIANCES CORP.

(21) Appl. No.: 12/549,490

(22) Filed: Aug. 28, 2009

(30) Foreign Application Priority Data
Jan. 23, 2009 (CN) 200920067431.4

(51) Int. Cl. H05K 5/00

(52) U.S. Cl. 361/679.01

(57) ABSTRACT

An electrical device includes a housing, a cover removably positioned on the housing, and a releasing mechanism. The releasing mechanism includes a main body including a pusher, wherein the main body is movably positioned on the housing and is movable between a locked position and a released position, and the pusher is configured to slidably engage with the cover and gradually disengage the cover from the housing when the main body moves toward the released position.

### BACKGROUND

1. Technical Field

The present teaching relates generally to cover releasing mechanisms. Specifically, the present teaching relates to cover releasing mechanisms used for electrical devices.

2. Discussion of Related Art

With advances in technology, electrical devices are widely used for various purposes. Some electrical devices, such as for example, mobile phones may include a housing defining an opening thereon, and a cover removably positioned on the opening. Some items, such as for example, batteries and Subscriber Identity Model (SIM) cards, are positioned in the opening and covered by the cover. As such, the cover may be removed by a user to enable the access to such items for replacement or maintenance purpose.

In some known electrical devices, at least one protrusion is formed on the cover at a position at least approximating the edge of the opening, and the protrusion may engage with the finger of a user to facilitate holding the cover. Also in some known electrical devices, at least one recess is defined on the housing and at least approximates the edge of opening. As such, the user's finger may enter into such recess so as to engage with the edge of the cover. Still in some known electrical devices, a spring is provided to resiliently positioned against the cover, and the spring may push the cover away from the housing when the cover is in an unlocked condition.

However, it might still be inconvenient to remove the cover by utilizing the protrusion, the recess and/or the spring described above. In addition, in certain cases, the cover is tightly fitted in the opening of the housing. As such, it might be difficult to remove the cover through the protrusion and/or the recess, and the spring might not provide sufficient force to disengage the cover from the housing, either. Therefore, there is a need to provide a reliable and convenient cover releasing mechanism.

### SUMMARY OF THE PRESENT TEACHING

In one aspect, an electrical device is provided. The electrical device includes a housing, a cover removably positioned on the housing, and a releasing mechanism. The releasing mechanism includes a main body including a pusher, wherein the main body is movably positioned on the housing and is movable between a locked position and a released position, and the pusher is configured to slidably engage with the cover and gradually disengage the cover from the housing when the main body moves toward the released position.

In another aspect, a portable electrical device is provided. The electrical device includes a housing, a cover removably positioned on the housing, and a releasing mechanism. The releasing mechanism includes a main body including a latch and a pusher, wherein the main body is movably positioned with respect to at least one of the housing and the cover and is movable between a locked position and a released position, the latch is configured disengage from at least one of the housing and the cove when the main body moves toward the released position, and the pusher is configured to move to engage with said at least one of the housing and the cover when the main body moves toward the released position.

### BRIEF DESCRIPTION OF THE DRAWINGS

FIG. 1 is an exploded perspective view of an exemplary mobile phone, according to an embodiment of the present teaching;

FIG. 2 is a top perspective view of a cover applicable to the mobile phone of FIG. 1, according to an embodiment of the present teaching;

FIG. 3 is a bottom perspective view of a cover applicable to the mobile phone of FIG. 1, according to an embodiment of the present teaching;

FIG. 4 is a top perspective view of a cover releasing mechanism applicable to the mobile phone of FIG. 1, according to an embodiment of the present teaching;

FIG. 5 is a bottom perspective view of a cover releasing mechanism applicable to the mobile phone of FIG. 1, according to an embodiment of the present teaching;

FIG. 6 is a cross sectional view of the mobile phone of FIG. 1 when mounting the cover onto a housing, according to an embodiment of the present teaching;

FIG. 7 is a cross sectional view of the mobile phone of FIG. 1 when the cover is locked on the housing, according to an embodiment of the present teaching;

FIG. 8 is a cross sectional view of the mobile phone of FIG. 1 when moving a main body toward a released position, according to an embodiment of the present teaching; and

FIG. 9 is a cross sectional view of the mobile phone of FIG. 1 when the main body is in the released position, according to an embodiment of the present teaching.

### DETAILED DESCRIPTION

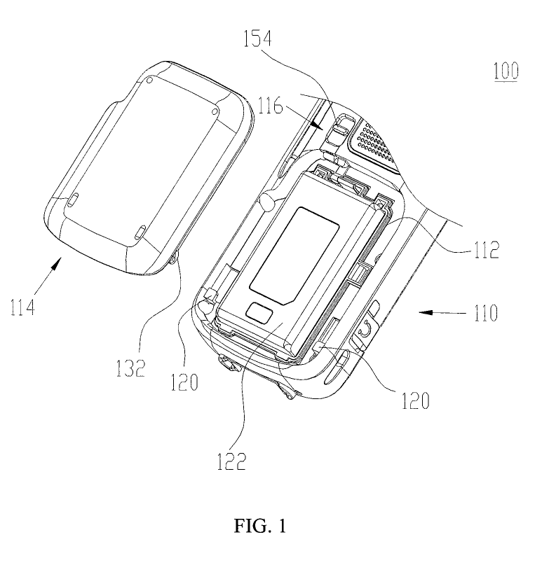

FIG. 1 is an exploded perspective view of an exemplary mobile phone 100 in which exemplary embodiments of the present teaching may be practiced and for which the benefits of the invention may be realized. The illustrated mobile phone 100 includes a housing 110 defining an opening 112 on a back surface thereof, and a cover 114 removably attachable to the housing 110. The cover 114 may be mounted onto the back surface of the housing 110, and may at least partially cover the opening 112. A cover releasing mechanism 116 is slidably positioned on the back surface of the housing 110, and may be manipulated to facilitate removing the cover 114 from the housing 110.

The illustrated opening 112 includes two retaining tabs 120 respectively formed on two opposite sidewalls of the opening 112 and approximating the lower end of the housing 110. A battery 122 is positioned within the opening 112 and is electrically connected with the electrical component (not shown) within the housing 110. The cover 114 is separately provided from the battery 122, and may be attached to the housing 110 for covering the battery 122 and/or securing the battery 122 within the opening 112. Alternatively, the battery 122 may be secured onto the cover 114, and engages with the electrical terminals (not shown) within the mobile phone 100 when the cover 114 is mounted onto the housing 110.

In a further exemplary embodiment, a seal member (not shown) is provided on the housing 110, and extends along the inner side surface of the opening 112. Alternatively, the seal member may be provided along the side walls of the cover 114. The seal member is sandwiched between the cover 114 and the inner side surface of the opening 112 when the cover 114 is mounted onto the housing 110. As such, the seal member may provide a dust tight or fluid tight seal between the cover 114 and the housing 110. In this embodiment, a higher force may be required to remove the cover 114 from the housing 110.

It is appreciated, however, that the herein described methods and apparatus may likewise be practiced in dust-proof and/or water-proof electrical devices and other general electrical devices. It is also appreciated that the herein described methods and apparatus may likewise be practiced in a variety of alternative electrical devices, such as for example, notebook computers, personal digital assistants, digital cameras, and other portable or non-portable electrical devices, with modification apparent to those in the art. Therefore, the mobile phone 100 as described and illustrated herein is for illustrative purposes only and is not intended to limit the herein described methods and apparatus in any aspect.

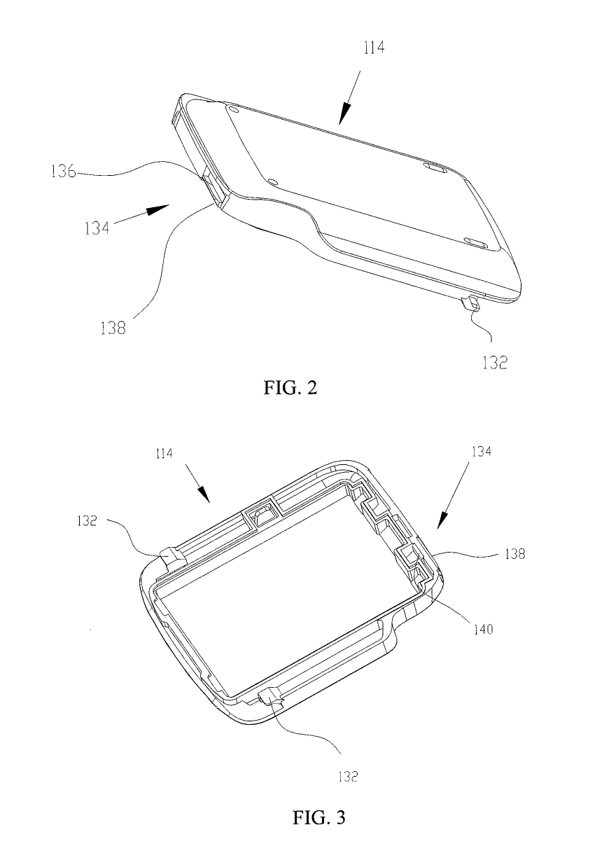

FIGS. 2 and 3 are perspective views of the cover 114 applicable to the mobile phone 100 from different angles. The illustrated cover 114 includes two protrusions 132 respectively formed on two sides thereof and approximating the lower end of the cover 114. An engagement portion 134 extends inwardly from the cover 114 at a position approximating the upper end of the cover 114, and is used to cooperate with the cover releasing mechanism 116 (shown in FIG. 1) to lock or release the cover 114.

In the illustrated embodiment, a retaining slot 136 is defined on the engagement portion 134 and is accessible from the upper surface of the cover 114. A first cover slant surface 138 and a second cover slant surface 140 are formed on the inner end of the engagement portion 134, and are positioned facing different directions.

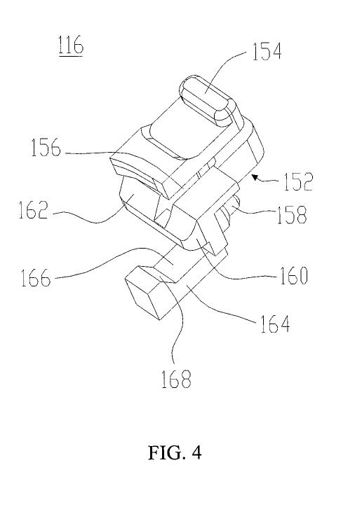

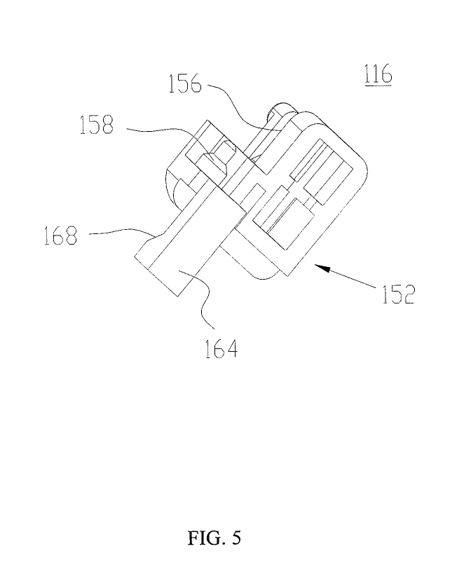

FIGS. 4 and 5 are perspective views of the cover releasing mechanism 116 applicable to the mobile phone 100 shown in FIG. 1 from different angles. The illustrated cover releasing mechanism 116 includes a main body 152 to be slidably mounted on the housing 110. The main body 152 includes a push button 154 formed on the a top portion thereof, and two guiding slots 156 defined respectively on two sides thereof. The push button 154 is exposed on the back surface of housing 110 when the main body 152 is mounted on the housing 110, and may be manipulated by a user to move the main body 152. The guiding slots 156 are defined beneath the push button 154, and are slidably engaged with the housing 110 through, such as for example, guiding ribs (not shown) formed on the housing 110. It should be understood that, in alternative embodiments, the main body 152 may be slidably mounted on the housing 110 by utilizing other known guiding mechanisms in lieu of the guiding slots.

The main body 152 also includes a guiding rod 158 extending forwardly from the main body 152, and a latch 160 extending backwardly from the main body 152. In an exemplary embodiment, the cross section of the latch 160 is substantially identical in shape and is slightly smaller in size with respect to the cross section of the retaining slot 136 (shown in FIG. 2). A latch slant surface 162 is formed on the rear end of the latch 160. A pusher 164 also extends backwardly from the main body 152 at a position below the latch 160. In one embodiment, the pusher 164 is integrally formed with the latch 160, and a receiving space 166 is defined between the latch 160 and the pusher 164. The space 166 is used to receive at least a portion of the engagement portion 134. The pusher 164 further includes a pusher slant surface 168 formed thereon, and the latch slant surface 162 and the pusher slant surface 168 are positioned facing different directions.

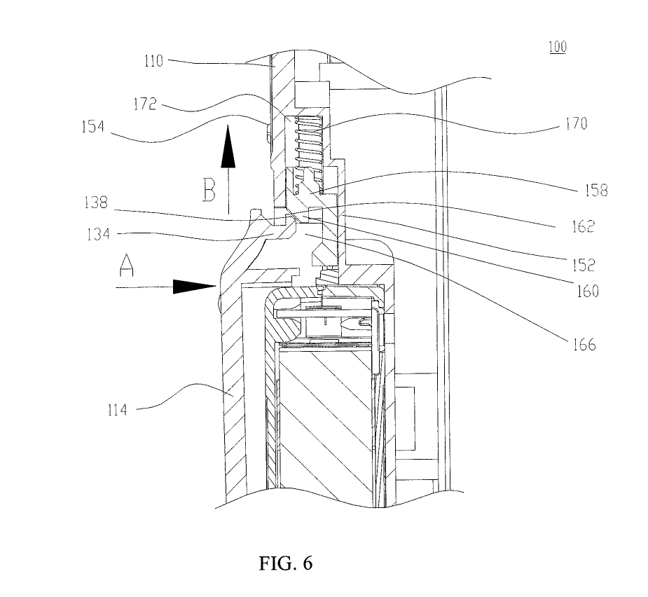

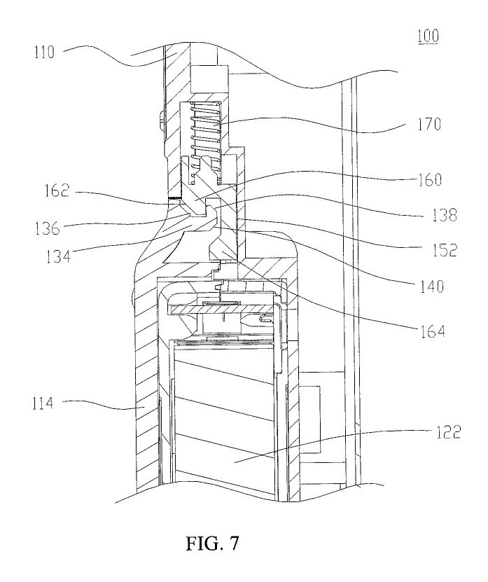

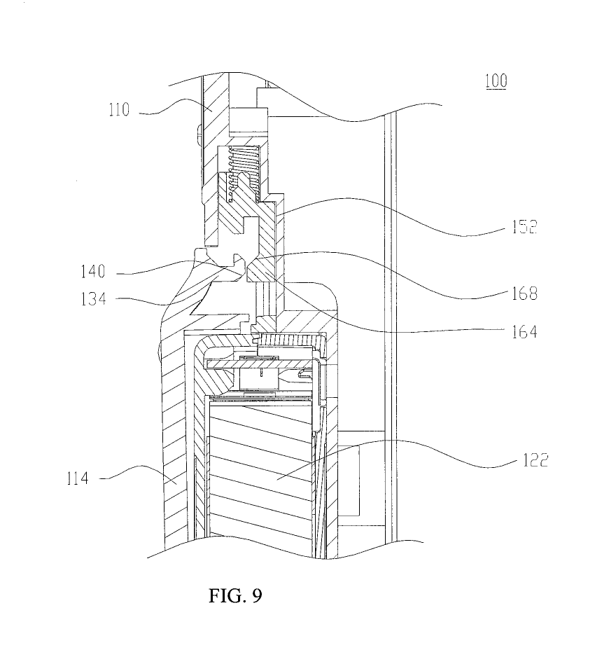

FIG. 6 is a cross sectional view of the mobile phone 100 when mounting the cover 114 onto the housing, and FIG. 7 is a cross sectional view of the mobile phone 100 when the cover 114 is locked on the housing 110. As described above, the main body 152 is slidably mounted on the housing 110, and is movable between a locked position (shown in FIG. 7) and a released position (shown in FIG. 9). The cover releasing mechanism 116 also includes a biasing member, such as for example, a compression spring 170 at least partially received in a spring channel 172 defined within the housing 110.

In the illustrated embodiment, a first end of the spring 170 abuts an inner wall of the spring channel 172, and a second end of the spring 170 is positioned around the guiding rod 158 of the main body 152. The second end of the spring 170 is secured on the guiding rod 158, and moves together with the main body 152. As such, the spring 170 resiliently abuts the main body 152, and biases the main body 152 toward the locked position.

In an exemplary process for mounting the cover 114 onto the housing 110, the lower end of the cover 114 is firstly secured onto the housing 110. Specifically, the protrusions 132 (shown in FIG. 2) of the cover 114 engages with the retaining tabs 120 (shown in FIG. 1) on the opening 112, respectively. As such, the lower end of the cover 114 is substantially fixed with respect to the housing 110, and the upper end of the cover 114 is movable toward or away from the housing 110. It should be understood that other known retaining structures, such as protrusions and retaining slots respectively provided on the opening and the cover may also be utilized to secure the cover onto the housing.

After securing the lower end of the cover 114 onto the housing 110, the upper end of the cover 114 is moved toward the housing 110. The main body 152 is remained in the locked position when there is no external force applied thereon. In addition, the first cover slant surface 138 is substantially positioned corresponding to the latch slant surface 162 when the upper end of the cover 114 approximates the housing 110. The engagement portion 134 of the cover 114 then engages with the latch 160, and pushes the main body 152 to move away from the locked position. Specifically, when the upper end of the cover 114 moves in a direction A shown in FIG. 6, the latch slant surface 162 slides on the first cover slant surface 138, and the main body 152 moves upwardly, i.e. moves in a direction B shown in FIG. 6.

Referring to FIG. 7, when the engagement portion 134 at least partially enters into the receiving space 166, the first cover slant surface 138 disengages from the latch slant surface 162. The main body 152 then moves back to the locked position under the biasing force of the spring 170, and the latch 160 enters into the retaining slot 136 of the engagement portion 134. As such, the upper end of the cover 114 is locked onto the housing 110 when the main body 152 is in the locked position. In the locked position, the battery 122 may be firmly positioned between the housing 110 and the cover 114, and the pusher 164 is disengaged with the cover 114.

In an alternative embodiment, when mounting the upper portion of the cover 114 onto the housing 110, the push button 154 is manipulated to move the main body 152 toward the released position. When the engagement portion 134 at least partially enters into the receiving space 166, the push button 154 is released. As such, the main body 153 moves back to the locked position, and the upper end of the cover 114 is locked onto the housing 110.

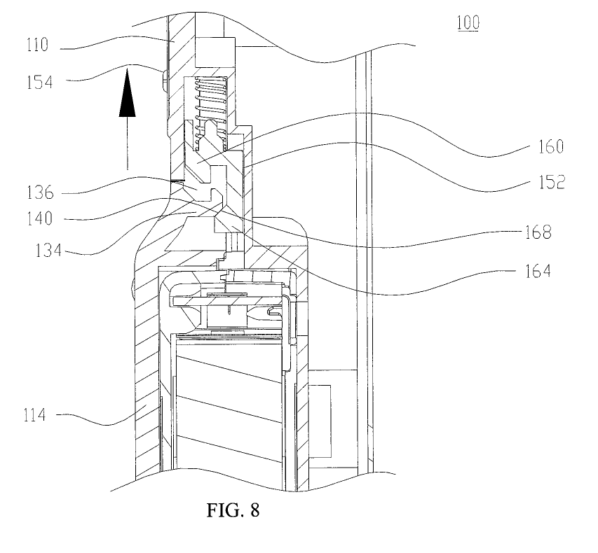

FIG. 8 is a cross sectional view of the mobile phone 100 when moving the main body 152 toward the released position, and FIG. 9 is a cross sectional view of the mobile phone 100 when the main body 152 is in the released position.

In an exemplary process for removing the cover 114, the push button 154 is manipulated to move the main body 152 from the locked position toward the released position. The latch 160 gradually disengages from the cover 114, and retreats from the retaining slot 136. After disengaging the latch 160 from the cover 114, the pusher 164 moves to engage with the engagement portion 134 of the cover 114. When the main body 152 moves further toward the released position, the pusher 164 slidably engages with the cover 114, and the pusher slant surface 168 slides on the second cover slant surface 140. As such, the upward movement of the pusher 164 drives the upper end of the cover 114 to move away from the housing 110.

Referring to FIG. 9, when the main body 152 moves to the released position, the pusher slant surface 168 disengages from the second cover slant surface 140, and the upper end of the cover 114 is at least partially disengaged from the housing 110. The cover 114 then may be removed from the housing 110 for replacement or maintenance of the items positioned behind the cover 114, such as for example, for recharging or replacing the battery 122 (shown in FIG. 1).

It should be understood that, in alternative embodiments, the cover releasing mechanism may also be slidably positioned on the cover, and the corresponding engagement portion may be formed on the housing. As such, a user may remove the cover from the housing by manipulating the main body movably positioned on the cover. Therefore, the structure and the position of the cover releasing mechanism as described and illustrated herein is for illustrative purposes only, and may be varied with modification apparent to those in the art.

By utilizing the cover releasing mechanism according to present teaching, the unlocking and disengagement of the cover may be realized by a single movement of the main body of the cover releasing mechanism. As such, a relatively convenient and reliable cover releasing function is achieved.

While the inventions have been described with reference to the certain illustrated embodiments, the words that have been used herein are words of description, rather than words of limitation. Changes may be made, within the purview of the appended claims, without departing from the scope and spirit of the invention in its aspects. Although the inventions have been described herein with reference to particular structures, acts, and materials, the invention is not to be limited to the particulars disclosed, but rather can be embodied in a wide variety of forms, some of which may be quite different from those of the disclosed embodiments, and extends to all equivalent structures, acts, and, materials, such as are within the scope of the appended claims.

What is claimed is:

1. An electrical device, comprising:
a housing;
a cover removably positioned on the housing; and
a releasing mechanism comprising a main body including a pusher, wherein the main body is movably positioned on the housing and is movable between a locked position and a released position, and the pusher is configured to slidably engage with the cover and gradually disengage the cover from the housing when the main body moves toward the released position.

2. The electrical device according to claim 1, wherein the main body further comprises a latch configured to disengage from the cover when the main body moves toward the released position.

3. The electrical device according to claim 2, wherein the latch and the pusher define a space therebetween, and the space is configured to receive at least a portion of the cover.

4. The electrical device according to claim 2, wherein the cover comprises a first slant surface configured to engage with the main body and push the main body toward the released position when mounting the cover onto the housing.

5. The electrical device according to claim 4, wherein the latch comprises a second slant surface configured to slidably engage with the first slant surface of the cover when mounting the cover onto the housing.

6. The electrical device according to claim 2, wherein the latch is integral with the pusher.

7. The electrical device according to claim 1, wherein the pusher further comprises a third slant surface configured to slidably engage with the cover when the main body moves toward the released position.

8. The electrical device according to claim 1, wherein the pusher is disengaged with the cover in the locked position.

9. The electrical device according to claim 1, wherein the releasing mechanism further comprises a spring biasing the main body toward the locked position.

10. The electrical device according to claim 1, wherein the housing further comprises a guiding mechanism guiding the main body to move between the locked position and the released position.

11. A portable electrical device, comprising:
a housing;
a cover removably positioned on the housing; and
a releasing mechanism comprising a main body including a latch and a pusher, wherein the main body is movably positioned with respect to at least one of the housing and the cover and is movable between a locked position and a released position, the latch is configured disengage from at least one of the housing and the cove when the main body moves toward the released position, and the pusher is configured to move to engage with said at least one of the housing and the cover when the main body moves toward the released position.

12. The portable electrical device according to claim 11, wherein the latch is integral with the pusher.

13. The portable electrical device according to claim 11, wherein the pusher further comprises a slant surface configured to movably engage with one of the housing and the cover when the main body moves toward the released position.

14. The portable electrical device according to claim 11, wherein the latch and the pusher define a space therebetween, and the space is configured to at least partially receive one of the housing and the cover.

15. The portable electrical device according to claim 11, wherein the releasing mechanism further comprises a spring biasing the main body toward the locked position.

16. The portable electrical device according to claim 11, wherein the housing further comprises a guiding mechanism guiding the main body to move between the locked position and the released position.
